(19) United States
(12) Patent Application Publication
(10) Pub. No.: US 2013/0051060 A1
(43) Pub. Date: Feb. 28, 2013

(54) INDEPENDENT VEHICLE LIGHTING SYSTEM

(71) Applicant: Robert J. Rhodes, North Olmsted, OH (US)

(72) Inventor: Robert J. Rhodes, North Olmsted, OH (US)

(21) Appl. No.: 13/696,997

(22) PCT Filed: May 9, 2011
(86) PCT No.: PCT/US11/35786

§ 371 Date: Nov. 8, 2012

Related U.S. Application Data
(60) Provisional application No. 61/333,070, filed on May 10, 2010.

(51) Int. Cl. B60Q 1/00; H05K 3/30; B60Q 1/46; B60Q 1/04; B60Q 1/34; B60Q 1/44

(52) U.S. Cl. 362/541; 362/459; 362/540; 362/542; 362/543; 29/832

(57) ABSTRACT

A comprehensive system for providing elements to make a personal vehicle safe and legal for driving on common streets. The system includes all lighting elements that make a personal vehicle street-legal and safe within a single package to allow for easy additions to existing vehicles. Combined elements may include headlights, turning signals, running/parking lights, brake lights, a horn, and windshield wipers.

This patent application claims priority to provisional patent No. U.S. 61/333,070 filed on May 10, 2010, and this provisional patent application is herein wholly incorporated within the present application.

FIELD OF INVENTION

This invention relates generally to auxiliary vehicle systems and, more specifically, to a comprehensive electrical system for insertion onto a personal vehicle.

### BACKGROUND

Golf carts have been constructed for transportation around grass-covered golf courses. All-terrain vehicles have been constructed for driving along muddy and rough paths instead of on streets. Bicycles and electric bicycles are increasingly moving from a sidewalk sport to a viable form of transportation as people utilize bikes to commute to work and run errands. These are all different examples of personal vehicles, and now many personal vehicles, though created for off-road purposes, are increasingly driven on streets alongside cars and trucks.

### SUMMARY

Personal vehicles include vehicles such as bicycles, electric bicycles, golf carts, Amish buggies, carriages, all-terrain vehicles (ATVs), utility vehicles, mules, four-wheelers, remote access vehicles, and many others. Each of these vehicles is an example of a transport carrier that a driver may use on private land, but may wish to use on a public street as well. However, many drivers are constrained from taking these vehicles to the streets, either by laws or by safety concerns. By adding a comprehensive system of turn signals, headlights, brake lights, license lights, hazard lights, brake lights, and a horn, a personal vehicle may meet legal and safety requirements for driving on common streets.

### DRAWINGS

FIGS. 1-2 are diagrams showing differing views of a frontward and rear position, respectively, for a personal vehicle that has been legalized for common street driving.

FIG. 3 is a diagram incorporating the lighting system within a non-electrical-powered personal vehicle.

FIG. 4 is a schematic diagram of the electrical lighting system.

FIG. 5 is a schematic diagram showing a specific connection option for an electrical-powered personal vehicle.

FIG. 6 is a schematic diagram showing a specific connection option for a non-electrical-powered personal vehicle.

### DETAILED DESCRIPTION

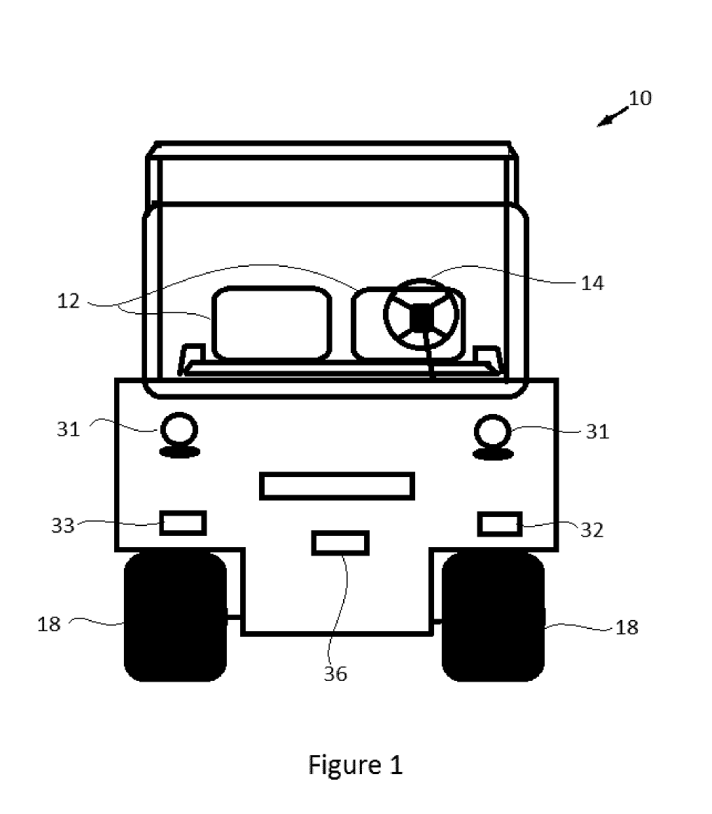

FIG. 1 illustrates a personal vehicle 10 with an electrical kit 80 attached as individual elements 30. Personal vehicles 10 (including golf carts, bicycles, electric bicycles, Amish buggies, carriages, all-terrain vehicles (ATVs), four-wheelers, utility vehicles, mules, remote access vehicles, and other vehicles not designed for street-driving purposes but physically able to be utilized on common streets) often are built and applied for purposes outside of normal driving down common streets. Common-street driving is primarily dominated by passenger vehicles such as cars and trucks. Such detours may not be the primary purpose of these personal vehicles 10, but it is not uncommon for such vehicles to be driven down a common street for both short and lengthy stretches. Some governments have taken official notice of these actions and are implementing new laws. Some laws give a greater number of rights to bicycle riders. Other related laws require all vehicles to meet a particular set of standards before being driven down a government-maintained street.

The standards behind many of the laws governing the use of personal vehicles 10 on common roads is often based on and related to the safety of the personal vehicle driver. Laws may differ by location, but common safety steps may be implemented in many locations, regardless of the laws governing the personal vehicle 10. Laws and safety focus on proper lighting elements 30 that can be displayed to keep other vehicles on the street better informed of the personal vehicle driver location and intentions. These lighting elements 30 may include brake lights, turn signals, headlights, hazard lights, license-illuminating lights, and possibly running lights (aka parking lights). Additional elements 30 that may be desired could include a horn, a windshield wiper, accessory outlet (allowing an owner to provide power to an accessory of his/her choice), etc.

For personal vehicles 10 that are not street-legal as new laws take effect, it will be difficult and expensive to update them for common-road-driving by separately adding each of the required elements. An owner would have to hire a mechanic to make the installations since the system would be difficult. Other difficulties with such a random method of updating include haphazard placement of controls in a variety of locations, failure of the added parts would be high due to the large number of pieces involved and locations for wires to be loosened. Also, in the case of an electrical failure, it could be difficult to locate a bad wire/connection due to the unorganized placement of the wires.

The present invention relates to a wholly-inclusive system 22. This system allows for mounting of a single, controlling system unit 20 with clearly marked functions, a limited and manageable number of quasi-protected or weather-resilient wires that are coded in a way that allows a non-electrician owner to make his/her own installations, and a power-pull architecture 60 for the system that does not significantly damage the power-storage units 61 during use.

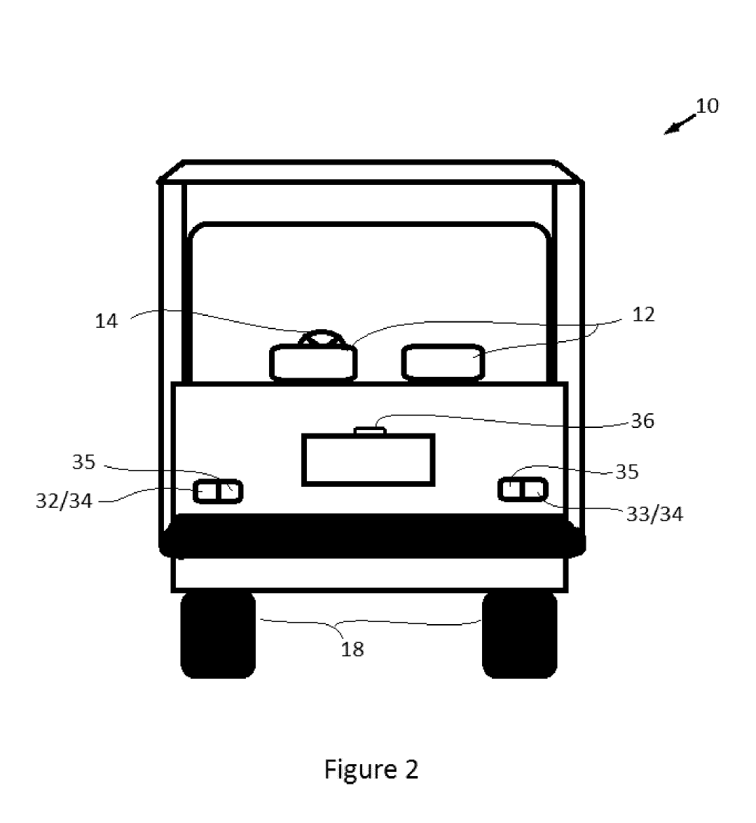

FIGS. 1 and 2 show the personal vehicle 10 after the electrical elements 30 have been added to the structure. Many of the elements 30 are positioned in locations relative to a traditional passenger vehicle (i.e. cars, trucks, etc.). It should be noted that due to the wide variety of personal vehicles on the market, different combinations of the electric elements 30 will be required. Some personal vehicles 10 come with headlights and/or running lights already installed. For these vehicles, it would be redundant to attach additional lights in such areas. The claimed invention encompasses an adaptive system that can adjust to the necessities of a personal vehicle owner.

Many electrical systems 30 will include an innovative turn signal system 32, 33. The turn signals 32, 33 can incorporate a timing mechanism 72 instead of or in addition to a turn-sensing mechanism 74. This would allow the driver or a system manufacturer to include a predetermined time (i.e. 2 seconds, 4 seconds, 6 seconds, 8 seconds, 10 seconds, 20 seconds, 30 seconds, etc.) that the turn signal 32, 33 would be in an “on” position. Alternatively, the driver would have the option of adjusting the timing to suit his or her preferences. Upon expiration of that time, the turn signal 32, 33 would turn off without regard to whether or not the vehicle driver turned. This could eliminate the need for a turn-sensing mechanism. Such a development would also create an environment where the driver would not need to turn off a signal after actions that do not register on a turn-sensing mechanism (i.e. switching lanes, making only a shallow turn).

Each of the electrical elements 30 are coordinated by a controlling system unit 20. Such a controlling unit may be flexibly mounted in a location preferred by a driver. Depending on driver preferences, a controlling unit 20 may be formed in different shapes, sizes, and designs. For example, a personal vehicle controlling unit may be mounted within a box that sits next to the driver, on a keypad that sits on the steering wheel of the vehicle, on a skin formed to fit the dashboard or handlebars of the vehicle, etc.). The controlling unit 20 is the location of multiple switches that turn the electrical elements off and on. Switches may be of the toggle variety, push-button variety, conductance variety, radio-signal variety, magnetic variety, etc. A distinct feature of the controlling unit 20 should be water/weather resistance.

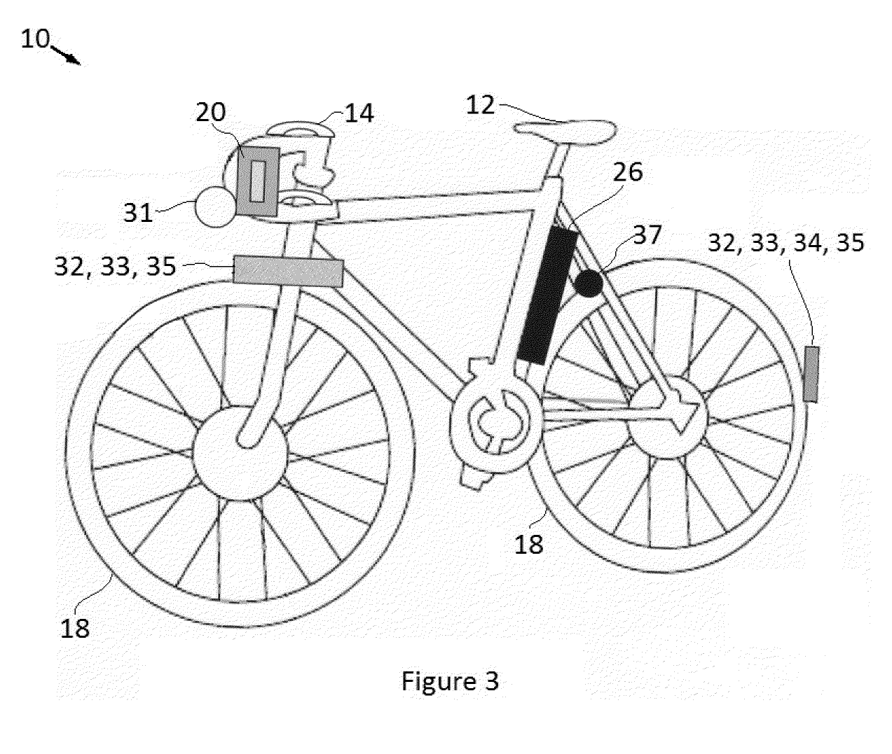

FIG. 3 depicts the lighting system as embodied in a non-electrically-powered personal vehicle. Although the lighting elements 30 are the same as in previous figures, many traditional personal vehicles, including bicycles, do not incorporate a power storage unit. In FIG. 3, the power storage 61 is added to the personal vehicle frame to provide power for use by the lighting elements 30. Of course, electric bicycles have a battery incorporated so no separate power storage would need to be added. Thus, for personal vehicles with a preexisting power storage unit 30 the lighting system may tap into already-stored power. However, if no power storage 30 is initially included as part of the personal vehicle, then the lighting system is able to incorporate power storage as a cohesive structure with each of the lighting elements.

It is worth noting that certain challenges are unique to installing a comprehensive system on smaller personal vehicles 10, such as bicycles, where the entire system of lighting elements 30 has an increased exposure to rain, wind, and other natural and corrosive elements during outdoor use. Extra steps can be taken to ensure longevity of the electrical elements 30 through strategically weatherizing (i.e. threading any connectors through the frame of the personal vehicle, encasing connectors in a protecting sheath, employing multiple-conductor cables, etc.).

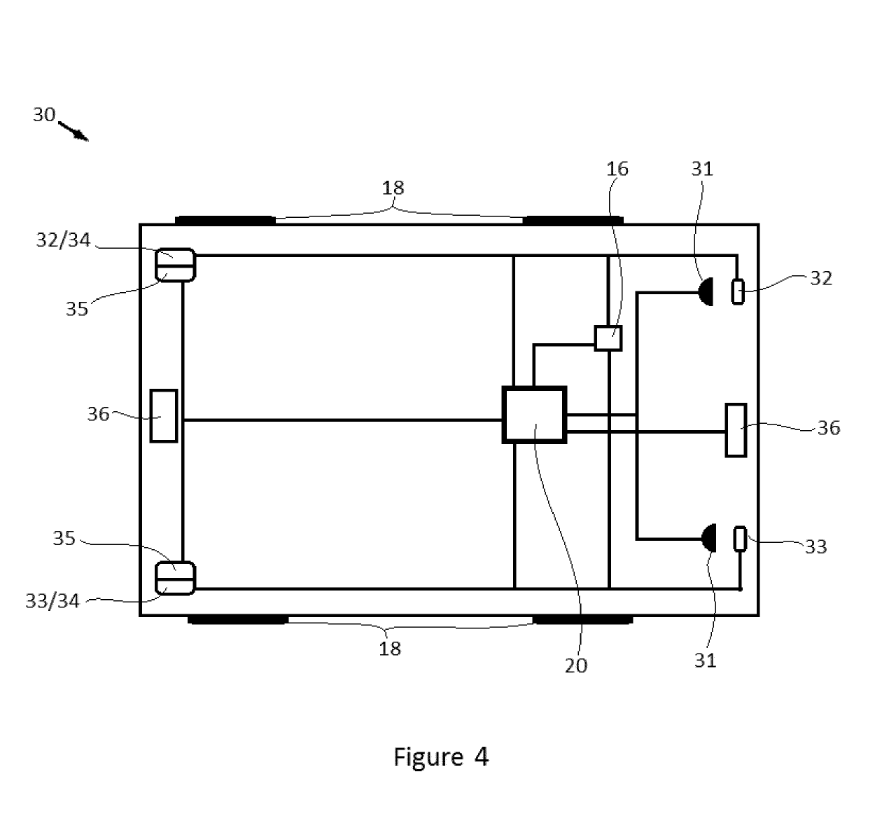

FIG. 4 demonstrates how the system 30 is suitable for installation by a non-electrician-owner. The system 30 may be organized and labeled in such manner to demonstrate proper installation methods. Labels 50 may include colors, letters, shapes, patterned wires or inserts, mating connectors, etc. It is contemplated to package the entire system already assembled. In this way a non-electrician owner can simply place the electrical elements 30 where the owner wishes with minimal to no knowledge of electrical circuits. Although the system 30 is currently shown with connecting wires, it is possible and contemplated to eliminate wires through optional wireless control (i.e. radio frequency interference).

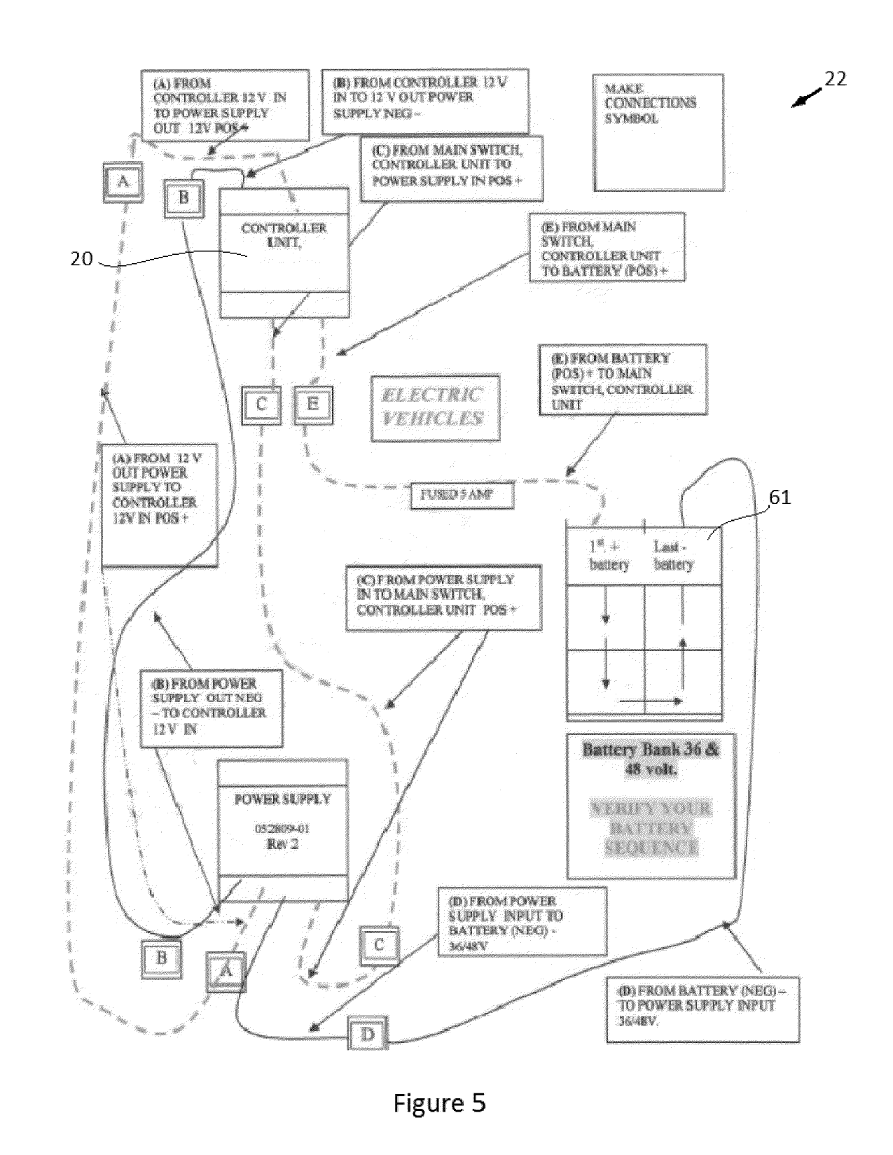

FIG. 5 illustrates the lighting system 30 as applied to an electrical-powered vehicle. Such a system 30 has a focus of avoiding excessive draw from a single battery, thereby increasing the life of the electrical power system 61 through installation that can be accomplished by a non-electrician owner. Depending on the differing power needs of the systems, one or more converters may be incorporated within the lighting system 30.

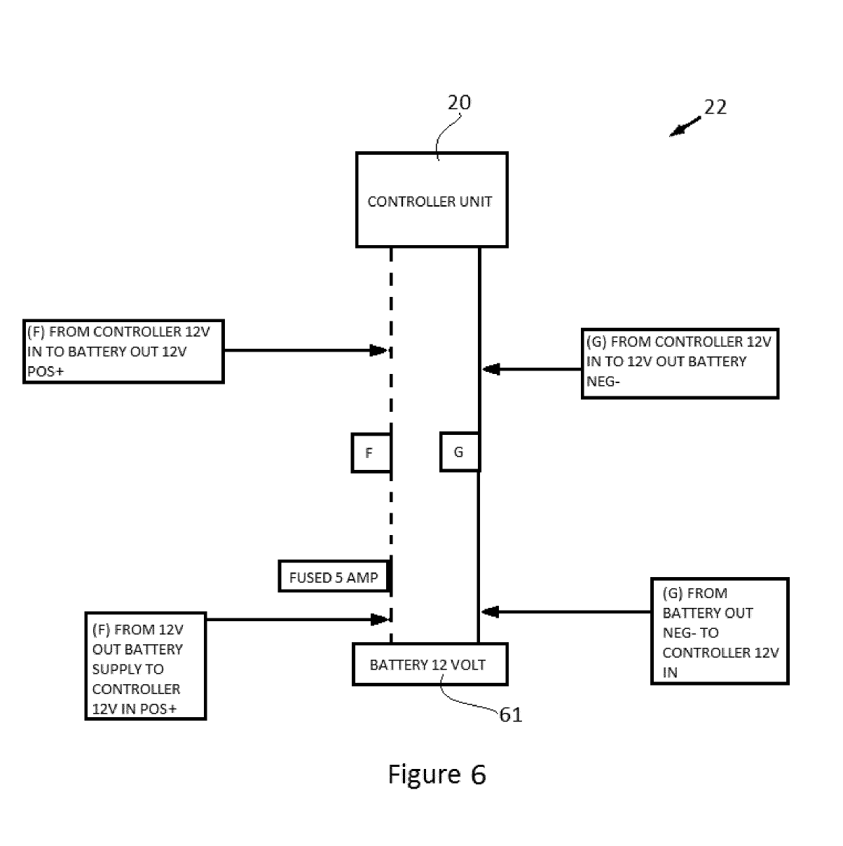

FIG. 6 demonstrates the street-legalizing system 30 as applied to a non-electrical-powered personal vehicle (e.g. a gasoline-powered, human-powered, animal-powered, etc.). It should be noted that this figure shows a system 30 reliant on battery power from independently mounted batteries. This is but one optional state for pulling power to run the lights. Alternative power sources are also considered to serve this purpose.

Although the system has been shown and described in a particular manner, equivalent modifications and alterations will occur to those skilled in the art after reading and studying this specification. Such alterations are obvious and incorporated within the current disclosure as all features described hereinabove may be combined in a multiplicity of ways that may or may not have been explicitly described in the present application.

1. A modular circuit unit, for attachment to a vehicle, comprising:
a multiplicity of individualized electrical elements able to produce a physical signal;
a controller electrically linked to each of the individualized elements and able to regulate the physical signal produced by the electrical elements;
wherein the modular circuit unit is comprehensively added to a vehicle;
wherein the modular circuit unit incorporates directives detailing how to comprehensively add said modular circuit unit to the vehicle.

2. A modular circuit unit as set forth in the preceding claim, wherein the electrical elements comprise a head lighting system for optional illumination mounted toward the front of the vehicle.

3. A modular circuit unit as set forth in claim 1, wherein the electrical elements further comprise a turn signal system for communicating directional intention.

4. A modular circuit unit as set forth in the preceding claim, wherein the turn signal system is linked to a timer allowing the turn signal system to disengage after a preset period of time has passed.

5. A modular circuit unit as set forth in claim 1, wherein the electrical elements further comprise a running lighting system.

6. A modular circuit unit as set forth in claim 1, wherein the electrical elements further comprise a brake lighting function for signaling a slowing or stopped vehicle position.

7. A modular circuit unit as set forth in claim 1, wherein the electrical elements further comprise a hazard-alerting method for bringing attention to the vehicle.

8. A modular circuit unit as set forth in claim 1, wherein the electrical elements further comprise an accessory outlet.

9. A modular circuit unit as set forth in claim 1, wherein the electrical components further comprise a license plate illuminator.

10. A modular circuit unit as set forth in claim 1, wherein at least one lighting element is comprised of a light-emitting diode.

11. A modular circuit unit as set forth in claim 1, wherein at least one electrical element is activated by a magnetic switch.

12. A modular circuit unit as set forth in claim 1, wherein at least one electrical element is activated by a radio signal.

13. A compact installation kit for a vehicle lighting system, comprising:
a multiplicity of distinct lighting elements comprising a headlight element, a turn signal element, a brake light element, a parking brake light element, a license light element, and a hazard light element;
at least one distinct non-lighting element including a horn element;
electrical wires connecting each of the lighting elements to a controller;
a controller able to communicate with the lighting elements to produce physical results;
a packaging system that organizes the electrical wires and lighting elements and labels the electrical wires in a specific format;
an installation guide providing instructions on how to attach the controller, lighting elements, and electrical wires to vehicle with references to the packaging system and labels.

14. A compact installation kit as set forth in the preceding claim, wherein the electrical components are attached to the vehicle through a mounting system.

15. A compact installation kit as set forth in claim 13, wherein the vehicle lighting system is resistant to water.

16. A method of retrofitting a vehicle with a controller and individualized electrical components,
wherein the controller responds to switches that may be activated to relay signals through a printed circuit board to the electrical components,
wherein a series of organized electrical signals communicates with each of the electrical components to the printed circuit board, and
wherein the electrical components comprise:
a turn signal system located towards differing sides of the vehicle for communicating directional intentions,
a brake lighting function for signaling a slowing or stopped vehicle position, and
a hazard-alerting method for bringing attention to the vehicle.

17. A method as set forth in the preceding claim, wherein the electrical components further comprise a head lighting system for optional illumination mounted on the vehicle.

18. A method as set forth in claim 16, wherein the controller is specifically formed to fit within the vehicle.

17. A method as set forth in claim 16, wherein the controller is located in a position surrounding a steering wheel.

18. A method as set forth in claim 16, wherein the switches on the controller are comprised of mechanical toggle switches.

20. A method as set forth in claim 16, wherein the vehicle turn signal is linked to a timer to enable the turn signal to power off after a pre-determined amount of time has passed.
